(19) United States
(12) Patent Application Publication
(10) Pub. No.: US 2024/0319590 A1
(43) Pub. Date: Sep. 26, 2024

(54) Optical Device and Method of Manufacture

(71) Applicant: Taiwan Semiconductor Manufacturing Co., Ltd., Hsinchu (TW)

(72) Inventors: Yu-Hung Lin, Taichung City (TW); Yu-Yi Huang, Taipei City (TW); Chih-Hao Yu, Tainan City (TW); Yu-Ting Yen, Kaohsiung City (TW); Shih-Peng Tai, Xinpu Township (TW)

(21) Appl. No.: 18/186,413

(22) Filed: Mar. 20, 2023

(51) Int. Cl. G03F 7/00; G03F 7/075; G03F 7/09; G03F 7/16

(52) U.S. Cl. CPC G03F 7/0005; G03F 7/0757; G03F 7/091; G03F 7/167; G03F 7/7015

(57) ABSTRACT

Optical devices and methods of manufacture are presented in which a first mask is utilized for multiple purposes. Some methods include depositing a first mask over a support material, forming a concave surface in the support material through the first mask, and bonding the first mask to a first bonding layer over an optical interposer.

### BACKGROUND

Electrical signaling and processing are one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates formation of a first optical package, in accordance with some embodiments.

FIGS. 2A-2E illustrate formation of a concave surface substrate, in accordance with some embodiments.

FIG. 3 illustrates bonding the concave surface substrate to the first optical package, in accordance with some embodiments.

FIG. 4 illustrates formation of backside structures, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which a concave surface is formed utilizing a masking material, and in which the masking material is also used in a subsequent bonding process. However, the embodiments presented herein are intended to be illustrative and are not intended to limit the embodiments to the precise descriptions as discussed. Rather, the embodiments discussed may be incorporated into a wide variety of implementations, and all such implementations are fully intended to be included within the scope of the embodiments.

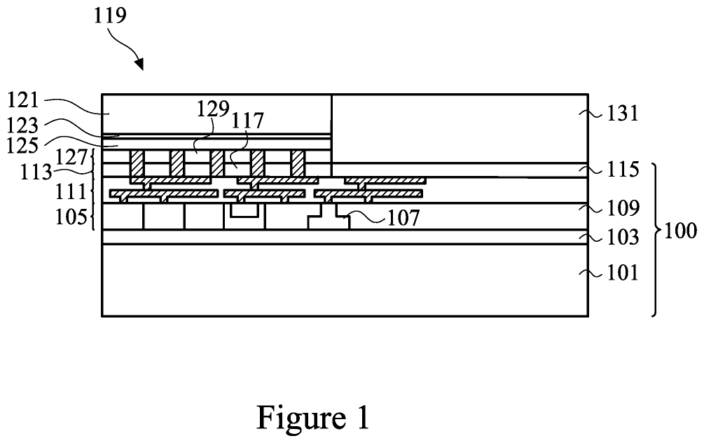

With reference now to FIG. 1, there is illustrated an optical interposer 100, in accordance with some embodiments. In the particular embodiment illustrated in FIG. 1, the optical interposer 100 is a photonic integrated circuit (PIC) and comprises a first substrate 101, a first insulator layer 103, and a layer of material (not separately labeled in FIG. 1 as it is formed into a first active layer 105 of first optical components 107). In an embodiment, at a beginning of the manufacturing process of the optical interposer 100, the first substrate 101, the first insulator layer 103, and the layer of material for the first active layer 105 of first optical components 107 may collectively be part of a silicon-on-insulator (SOI) substrate. Looking first at the first substrate 101, the first substrate 101 may be a semiconductor material such as silicon or germanium, a dielectric material such as glass, or any other suitable material that allows for structural support of overlying devices.

The first insulator layer 103 may be a dielectric layer that separates the first substrate 101 from the overlying first active layer 105 and can additionally, in some embodiments, serve as a portion of cladding material that surrounds the subsequently manufactured first optical components 107 (discussed further below). In an embodiment the first insulator layer 103 may be silicon oxide, silicon nitride, germanium oxide, germanium nitride, combinations of these, or the like, formed using a method such as implantation (e.g., to form a buried oxide (BOX) layer) or else may be deposited onto the first substrate 101 using a deposition method such as chemical vapor deposition, atomic layer deposition, physical vapor deposition, combinations of these, or the like. However, any suitable material and method of manufacture may be used.

The material for the first active layer 105 is initially (prior to patterning) a conformal layer of material that will be used to begin manufacturing the first active layer 105 of the first optical components 107. In an embodiment the material for the first active layer 105 may be a translucent material that can be used as a core material for the desired first optical components 107, such as a semiconductor material such as silicon, germanium, silicon germanium, combinations of these, or the like, while in other embodiments the material for the first active layer 105 may be a dielectric material such as silicon nitride or the like, although in other embodiments the material for the first active layer 105 may be III-V materials, lithium niobate materials, or polymers. In embodiments in which the material of the first active layer 105 is deposited, the material for the first active layer 105 may be deposited using a method such as epitaxial growth, chemical vapor deposition, atomic layer deposition, physical vapor deposition, combinations of these, or the like. In other embodiments in which the first insulator layer 103 is formed using an implantation method, the material of the first active layer 105 may initially be part of the first substrate 101 prior to the implantation process to form the first insulation layer 103. However, any suitable materials and methods of manufacture may be utilized to form the material of the first active layer 105.

Once the material for the first active layer 105 is ready, the first optical components 107 for the first active layer 105 are manufactured using the material for the first active layer 105. In embodiments the first optical components 107 of the first active layer 105 may include such components as optical waveguides (e.g., ridge waveguides, rib waveguides, buried channel waveguides, diffused waveguides, etc.), couplers (e.g., grating couplers, edge couplers, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable first optical components 107 may be used.

To begin forming the first active layer 105 of first optical components 107 from the initial material, the material for the first active layer 105 may be patterned into the desired shapes for the first active layer 105 of first optical components 107. In an embodiment the material for the first active layer 105 may be patterned using, e.g., one or more photolithographic masking and etching processes. However, any suitable method of patterning the material for the first active layer 105 may be utilized. For some of the first optical components 107, such as waveguides or edge couplers, the patterning process may be all or at least most of the manufacturing that is used to form these first optical components 107 components.

For those components that utilize further manufacturing processes, such as Mach-Zehnder silicon-photonic switches that utilize resistive heating elements, additional processing may be performed either before or after the patterning of the material for the first active layer 105. For example, implantation processes, additional deposition and patterning processes for different materials (e.g., resistive heating elements, III-V materials for converters), combinations of all of these processes, or the like, can be utilized to help further the manufacturing of the various desired first optical components 107. In some embodiments an epitaxial deposition of a semiconductor material such as germanium (used, e.g., for electricity/optics signal modulation and transversion) may be performed on a patterned portion of the material of the first active layer 105. In such an embodiment the semiconductor material may be epitaxially grown in order to help manufacture, e.g., a photodiode for an optical-to-electrical converter. All such manufacturing processes and all suitable first optical components 107 may be manufactured, and all such combinations are fully intended to be included within the scope of the embodiments.

Once the individual first optical components 107 of the first active layer 105 have been formed, a second insulating layer 109 may be deposited to cover the first optical components 107 and provide additional cladding material. In an embodiment the second insulator layer 109 may be a dielectric layer that separates the individual components of the first active layer 105 from each other and from the overlying structures and can additionally serve as another portion of cladding material that surrounds the first optical components 107. In an embodiment the second insulator layer 109 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the second insulating layer 109 has been deposited, the material may be planarized using, e.g., a chemical mechanical polishing process in order to either planarize a top surface of the second insulating layer 109 (in embodiments in which the second insulating layer 109 is intended to fully cover the first optical components 107) or else planarize the second insulating layer 109 with top surfaces of the first optical components 107. However, any suitable material and method of manufacture may be used.

Once the first optical components 107 of the first active layer 105 have been manufactured and the second insulating layer 109 has been formed, first metallization layers 111 are formed in order to electrically connect the first active layer 105 of first optical components 107 to control circuitry, to each other, and to subsequently attached devices. In an embodiment the first metallization layers 111 are formed of alternating layers of dielectric and conductive material and may be formed through any suitable processes (such as deposition, damascene, dual damascene, etc.). In particular embodiments there may be multiple layers of metallization used to interconnect the various first optical components 107, but the precise number of first metallization layers 111 is dependent upon the design of the optical interposer 100.

Optionally, during the manufacture of the first metallization layers 111, one or more second optical components (not separately illustrated) may be formed as part of the first metallization layers 111. In some embodiments the second optical components of the first metallization layers 111 may include such components as couplers (e.g., edge couplers, grating couplers, etc.) for connection to outside signals, optical waveguides (e.g., ridge waveguides, rib waveguides, buried channel waveguides, diffused waveguides, etc.), optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable optical components may be used for the one or more second optical components.

In an embodiment the one or more second optical components may be formed by initially depositing a material for the one or more second optical components. In an embodiment the material for the one or more second optical components may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, any suitable material and any suitable method of deposition may be utilized.

Once the material for the one or more second optical components has been deposited or otherwise formed, the material may be patterned into the desired shapes for the one or more second optical components. In an embodiment the material of the one or more second optical components may be patterned using, e.g., one or more photolithographic masking and etching processes. However, any suitable method of patterning the material for the one or more second optical components may be utilized.

For some of the one or more second optical components, such as waveguides or edge couplers, the patterning process may be all or at least most manufacturing that is used to form these components. Additionally, for those components that utilize further manufacturing processes, such as Mach-Zehnder silicon-photonic switches that utilize resistive heating elements, additional processing may be performed either before or after the patterning of the material for the one or more second optical components. For example, implantation processes, additional deposition and patterning processes for different materials, combinations of all of these processes, or the like, and can be utilized to help further the manufacturing of the various desired one or more second optical components. All such manufacturing processes and all suitable one or more second optical components may be manufactured, and all such combinations are fully intended to be included within the scope of the embodiments.

Once the one or more second optical components of the first metallization layers 111 have been manufactured, a first bonding layer 113 is formed over the first metallization layers 111. In an embodiment, the first bonding layer 113 may be used for a dielectric-to-dielectric and metal-to-metal bond. In accordance with some embodiments, the first bonding layer 113 includes a first dielectric material 115 such as silicon oxide, silicon nitride, or the like. The first dielectric material 115 may be deposited using any suitable method, such as CVD, high-density plasma chemical vapor deposition (HDPCVD), PVD, atomic layer deposition (ALD), or the like. However, any suitable materials and deposition processes may be utilized.

Once the first dielectric material 115 has been formed, first openings in the first dielectric material 115 are formed to expose conductive portions of the underlying layers in preparation to form first bond pads 117 within the first bonding layer 113. Once the first openings have been formed within the first dielectric material 115, the first openings may be filled with a seed layer and a plate metal to form the first bond pads 117 within the first dielectric material 115. The seed layer may be blanket deposited over top surfaces of the first dielectric material 115 and the exposed conductive portions of the underlying layers and sidewalls of the openings and the second openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the first dielectric material 115 and sidewalls of the openings and the second openings before the seed layer. The barrier layer may comprise titanium, titanium nitride, tantalum, tantalum nitride, or the like.

Following the filling of the first openings, a planarization process, such as a CMP, is performed to remove excess portions of the seed layer and the plate metal, forming the first bond pads 117 within the first bonding layer 113. In some embodiments a bond pad via (not separately illustrated) may also be utilized to connect the first bond pads 117 with underlying conductive portions and, through the underlying conductive portions, connect the first bond pads 117 with the first metallization layers 111.

Additionally, the first bonding layer 113 may optionally include one or more third optical components (not separately illustrated) incorporated within the first bonding layer 113. In such an embodiment, prior to the deposition of the first dielectric material 115, the one or more third optical components may be manufactured using similar methods and similar materials as the one or more second optical components (described above), such as by being waveguides and other structures formed at least in part through a deposition and patterning process. However, any suitable structures, materials and any suitable methods of manufacture may be utilized.

Once the first bonding layer 113 has been formed, a first semiconductor device 119 may be bonded to the optical interposer 100. In some embodiments, the first semiconductor device 119 is an electronic integrated circuit (EIC—e.g., a device without optical devices) and may have a semiconductor substrate 121, a layer of active devices 123, an overlying interconnect structure 125, a second bond layer 127, and associated third bond pads 129. In an embodiment the semiconductor substrate 121 may be similar to the first substrate 101 (e.g., a semiconductor material such as silicon or silicon germanium), the active devices 123 may be transistors, capacitors, resistors, and the like formed over the semiconductor substrate 121, the interconnect structure 125 may be similar to the first metallization layers 111 (without optical components), the second bond layer 127 may be similar to the first bond layer 113, and the third bond pads 129 may be similar to the first bond pads 117. However, any suitable devices may be utilized.

In an embodiment the first semiconductor device 119 may be configured to work with the optical interposer 100 for a desired functionality. In some embodiments the first semiconductor device 119 may be a high bandwidth memory (HBM) module, an xPU, a logic die, a 3DIC die, a CPU, a GPU, a SoC die, a MEMS die, combinations of these, or the like. Any suitable device with any suitable functionality, may be used, and all such devices are fully intended to be included within the scope of the embodiments.

Once the first semiconductor device 119 has been prepared, the first semiconductor device 119 may be bonded to the optical interposer 100. In an embodiment the first semiconductor device 119 may be bonded to the optical interposer 100 using, e.g., a dielectric-to-dielectric and metal-to-metal bonding process. In such an embodiment the first semiconductor device 119 is bonded to the first bonding layer 113 of the optical interposer 100 by bonding both the first bond pads 117 to the third bond pads 129 and by bonding the dielectrics within the first bonding layer 113 to the dielectrics within the second bond layer 127. In this embodiment the top surfaces of the first semiconductor device 119 and the optical interposer 100 may first be activated utilizing, e.g., a dry treatment, a wet treatment, a plasma treatment, exposure to an inert gas, exposure to H₂, exposure to N₂, exposure to O₂, or combinations thereof, as examples. However, any suitable activation process may be utilized.

After the activation process the first semiconductor device 119 and the optical interposer 100 may be cleaned using, e.g., a chemical rinse, and then the first semiconductor device 119 is aligned and placed into physical contact with the optical interposer 100. The first semiconductor device 119 and the optical interposer 100 are then subjected to thermal treatment and contact pressure to bond the first semiconductor device 119 and the optical interposer 100. For example, the first semiconductor device 119 and the optical interposer 100 may be subjected to a pressure of about 200 kPa or less, and a temperature between about 25° C. and about 250° C. to fuse the first semiconductor device 119 and the optical interposer 100. The first semiconductor device 119 and the optical interposer 100 may then be subjected to a temperature at or above the eutectic point for material of the first bond pads 117, e.g., between about 150° C. and about 650° C., to fuse the metal bond pads. In this manner, the first semiconductor device 119 and the optical interposer 100 form a bonded device. In some embodiments, the bonded dies are subsequently baked, annealed, pressed, or otherwise treated to strengthen or finalize the bond.

Additionally, while the above description describes a dielectric-to-dielectric and metal-to-metal bonding process, this is intended to be illustrative and is not intended to be limiting. In yet other embodiments, the optical interposer 100 may be bonded to the first semiconductor device 119 by metal-to-metal bonding, or another bonding process. For example, the first semiconductor device 119 and the optical interposer 100 may be bonded by metal-to-metal bonding that is achieved by fusing conductive elements. Any suitable bonding process may be utilized, and all such methods are fully intended to be included within the scope of the embodiments.

Once the first semiconductor device 119 has been bonded, a gap-fill material 131 is deposited in order to fill the spaces around the first semiconductor device 119 and provide additional support. In an embodiment the gap-fill material 131 may be a material such as silicon oxide, silicon nitride, silicon oxynitride, combinations of these, or the like, deposited to fill and overfill the desired spaces. However, any suitable material and method of deposition may be utilized.

Once the gap-fill material 131 has been deposited, the gap-fill material 131 may be planarized in order to expose the first semiconductor device 119. In an embodiment the planarization process may be a chemical mechanical planarization process, a grinding process, or the like. However, any suitable planarization process may be utilized.

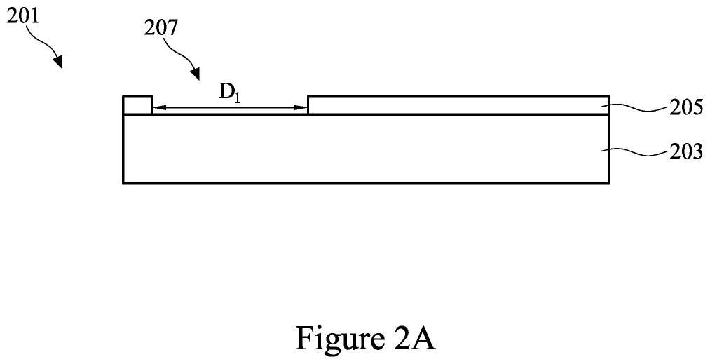

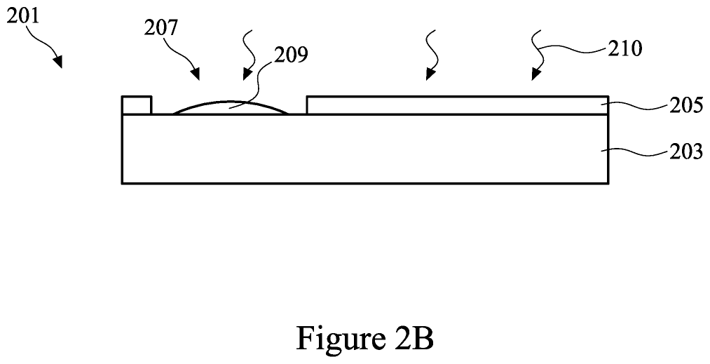

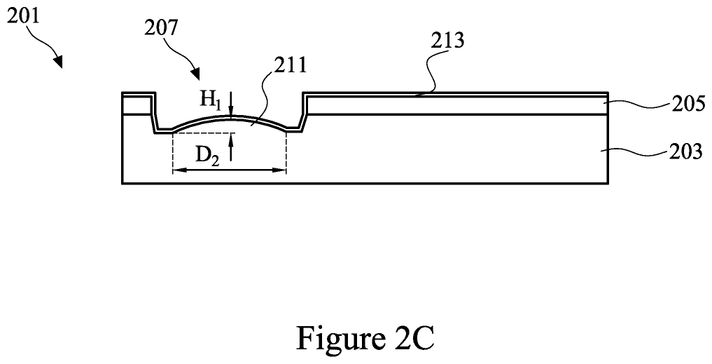

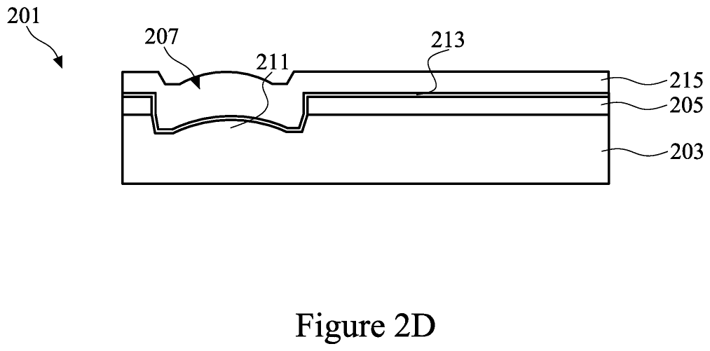

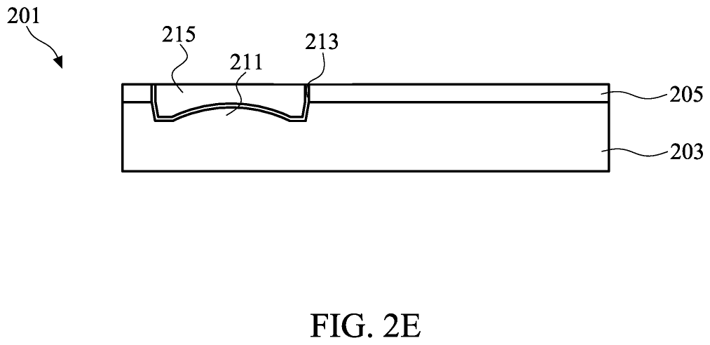

FIGS. 2A-2E illustrate formation of a concave surface substrate 201 that will subsequently be bonded to the structure of FIG. 1. Looking first at FIG. 2A, in an embodiment the concave surface substrate 201 comprises a support material 203 and a first mask 205. The support material 203 may be a material that is transparent to the wavelength of light that is desired to be used, such as silicon, SiO₂, Al₂O₃, combinations of these, or the like. However, any suitable material may be utilized.

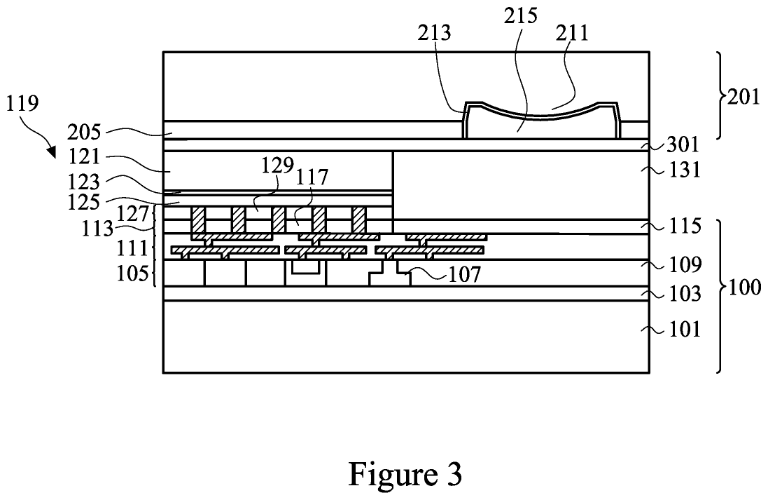

The first mask 205 is formed over the support material 203. In an embodiment the material for the first mask 205 is a material that may both be patterned for use as a mask and which may also be used in a subsequent bonding process (described further below with respect to FIG. 3). In particular embodiments the material for the first mask 205 may be a material such as silicon oxide, silicon oxynitride, silicon nitride, silicon carbide, multiple layers thereof (e.g., a composite mask), combinations of these, or the like, and may be formed using one or more deposition methods such as chemical vapor deposition, atomic layer deposition, physical vapor deposition, an oxidation process (e.g., when the support material 203 is a material such as silicon), combinations of these, or the like. Additionally, the material for the first mask 205 may be formed to a thickness of between about 0.01 μm and about 10 μm. However, any suitable material, method of manufacture, and thickness may be utilized.

Once the material for the first mask 205 has been deposited, the material for the first mask 205 is patterned to form a first opening 207. In an embodiment the patterning may be performed using a photolithographic masking and etching process, whereby a photosensitive material is placed, exposed, and developed in order to form a photomask, and the photomask is then used with one or more anisotropic etching process such as a reactive ion etch in order to etch through a portion of the first mask 205 and expose the underlying support material 203.

In an embodiment the first opening 207 is formed and shaped to expose the portion of the first mask 205 where a concave surface 211 (not separately illustrated in FIG. 2A but illustrated and discussed further below with respect to FIG. 2C) will be formed within the support material 203. In a particular embodiment the first opening 207 may be formed in a circular pattern (when viewed in a top down view) that has a first diameter D₁ of between about 20 μm and about 200 μm. However, any suitable shape and dimensions may be utilized.

FIG. 2B illustrates a placement and patterning of a second mask 209 within the first opening 207. In an embodiment the second mask 209 may be a photoresist which is placed (e.g., with a spin-on process), pre-baked, imaged, post-imaging baked, developed, and post-development baked in order to place the second mask 209 within the first opening 207. However, any suitable material and method of placing the second mask 209 may be utilized.

Additionally, once the second mask 209 has been placed, imaged, and developed, the second mask 209 may be reshaped in order to form the desired curved surface for the second mask 209. In an embodiment the second mask 209 is reshaped using a first annealing process (represented in FIG. 2B by the curved arrows labeled 210) different from the post-development bake (e.g., has a higher temperature than the post-development bake). In a particular embodiment the first annealing process 210 is a thermal anneal that uses a temperature of between about 100° C. and about 300° C. for a time period of between about 5 minutes and about 30 minutes. However, any suitable process or parameters may be utilized in order to reshape the second mask 209.

FIG. 2C illustrates formation of the concave surface 211 within the support material 203 using the second mask 209 through the first mask 205. In an embodiment the formation of the concave surface 211 may be performed using, for example, one or more anisotropic etching processes, such as a reactive ion etch, that uses the second mask 209 as a sacrificial mask. In particular, as the one or more etching processes begin to etch the exposed portions of the support material 203, the one or more etching processes will also begin to etch the material of the second mask 209. As the thinner portions of the second mask 209 (e.g., those portions along the outer edge of the second mask 209) are removed, additional portions of the underlying support material 203 that were previously cover by the second mask 209 become exposed to the one or more etching processes. Eventually, some, most, or all of the second mask 209 is consumed, causing different portions of the previously covered parts of the support material 203 to begin being etched at different times. In this fashion, the original curved shape of the second mask 209 is translated to the support material 203, thereby forming the concave surface 211 within the support material 203. However, any suitable process may be utilized.

In an embodiment the concave surface 211 may be formed in a circular shape (in a top down view) with a second diameter D₂ less than the first diameter D₁, such as by being between about 20 μm and about 500 μm. Additionally, the concave surface 211 may be formed with a first height H₁ of between about 2 μm and about 50 μm. However, any suitable dimensions may be utilized.

Additionally, in embodiments in which the second mask 209 is not fully consumed by the one or more etching processes, any remaining material of the second mask 209 may be removed once the concave surface 211 has been formed. In an embodiment in which the second mask 209 is a photoresist, the remains of the second mask 209 may be removed using a process such as ashing, whereby the temperature of the second mask 209 is raised until the second mask 209 undergoes a thermal decomposition and may be easily removed. However, any suitable method may be used.

FIG. 2C additionally illustrates formation of an anti-reflective coating (ARC) 213 over the concave surface 211 and over a top surface of the first mask 205. In an embodiment the ARC 213 may be one or more layers of materials which help to prevent undesired reflections as light is focused and/or traverses through the concave surface substrate 201. In a particular embodiment the one or more layers of materials may be materials such as silicon oxide, silicon nitride, Ta₂O₅, MgF₂, combinations of these, or the like, formed using processes such as chemical vapor deposition, atomic layer deposition, physical vapor deposition, oxidation, nitridation, combinations of these, or the like. Additionally, the ARC 213 may be formed to have a thickness of between about 0.2 μm and about 2 μm. However, any suitable materials, thicknesses, and methods of deposition may be utilized.

In a particular embodiment the ARC 213 may comprise multiples layers of material such as a first layer of silicon oxide and a first layer of silicon nitride formed over the first layer of silicon oxide. Additionally, in other embodiments a second layer of silicon oxide and a second layer of silicon nitride are be further deposited over the first layer of silicon oxide and the first layer of silicon nitride, thereby forming an alternating stack of silicon oxide and silicon nitride. However, any suitable combinations of materials may be utilized.

FIG. 2D illustrates a deposition of a fill material 215 to fill and/or overfill the first opening 207. In an embodiment the fill material 215 may be a dielectric material that is either the same or different from the first mask 205. In a particular embodiment the fill material 215 may be silicon oxide, polyimide, combinations of these, or the like, deposited using a method such as chemical vapor deposition, physical vapor deposition, atomic layer deposition, combinations of these, or the like. However, any suitable material and any suitable method of deposition may be utilized.

Additionally, if desired, dopants may be added to the fill material 215 in order to help adjust the desired properties of the fill material 215. In one such embodiment in which the optical properties are desired to be modified, a dopant such as carbon, silicon, hydrogen, oxygen combinations of these, or the like, may be added to the oxide material of the fill material 215 to a concentration of between about 0.1 at. % and about 95 at. %. However, any suitable dopant and any suitable concentration may be utilized.

FIG. 2E illustrates a planarization process that is used to remove excess material from outside of the first opening 207. In an embodiment the planarization process may be performed using a chemical mechanical polishing process, whereby etchants and abrasives are used collectively with a grinding process in order to remove undesired material. However, any other suitable planarization process, such as a grinding process or even one or more etching processes, may also be utilized.

Additionally, the planarization process additionally removes excess material of the ARC 213 from outside of the first opening 207. By removing the excess material of the ARC 213 the underlying material of the first mask 205 is re-exposed while still leaving the upper edges of the ARC 213 and the fill material 215 covered with the first mask 205 to a depth of between about 0.01 μm and about 10 μm. As such, the first mask 205 becomes available for subsequent bonding.

By leaving the first mask 205 in place during the planarization process used to remove the excess material of the ARC 213 and the fill material 215, the first mask 205 creates a wider process window for the deposition and planarization of the fill material 215 with less or smaller formation of dishing problems. Such a removal or reduction of problems related to dishing helps to increase the overall yield of the manufacturing process.

FIG. 3 illustrates a bonding of the concave surface substrate 201 to the structure of FIG. 1 in a wafer-on-wafer bonding process. In an embodiment the bonding process may be initiated by forming a third bonding layer 301 over the first semiconductor device 119 and the gap-fill material 131. In an embodiment the third bonding layer 301 may be used for fusion bonding (also referred to as oxide-to-oxide bonding), hybrid bonding, combinations of these, or the like. In accordance with some embodiments, the third bonding layer 301 is formed of a silicon-containing dielectric material such as silicon oxide, silicon nitride, or the like. The third bonding layer 301 may be deposited or otherwise formed using any suitable method, such as, atomic layer deposition (ALD), chemical vapor deposition (CVD), high-density plasma chemical vapor deposition (HDPCVD), physical vapor deposition (PVD), oxidation, nitridation, combinations of these, or the like to a thickness of between about 500 nm and about 1000 nm. However, any suitable material, process, and thickness may be utilized.

Optionally, if desired the third bonding layer 301 may be planarized after deposition in order to provide a more planar surface for subsequent bonding processes. In an embodiment the third bonding layer 301 may be planarized using a chemical mechanical polishing process. However, any other suitable process, such as a grinding process or even a series of one or more etching processes, may be utilized.

Once the third bonding layer 301 has been deposited and planarized, the third bonding layer 301 may be bonded to each of the first mask 205, the anti-reflective coating 213, and the fill material 215. To begin the process of bonding the third bonding layer 301 to the first mask 205, the surfaces of the third bonding layer 301 and the surfaces of the concave surface substrate 201 may initially be activated. Activating the top surfaces of the third bonding layer 301 and the concave surface substrate 201 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the hybrid bonding of the third bonding layer 301 and the concave surface substrate 201.

After the activation process, the third bonding layer 301 and the concave surface substrate 201 may be placed into physical contact. In an embodiment the third bonding layer 301 is placed into physical contact with the concave surface substrate 201 using, e.g., an alignment process in order to minimize overlay differences during the placement process. With the activation process chemically modifying the surfaces, the bonding process between the materials is begun upon the physical contact.

Once physical contact has begun the bonding process, the bonding may then be strengthened by subjecting the assembly to a thermal treatment. In an embodiment the third bonding layer 301 and the concave surface substrate 201 may be subjected to a temperature between about 200° C. and about 400° C. to strengthen the bond. In this manner, fusion of the third bonding layer 301 and the concave surface substrate 201 forms a bonded device.

Additionally, while specific processes have been described to initiate and strengthen the bonds between the third bonding layer 301 and the concave surface substrate 201, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

Also, while fusion bonding (e.g., oxide bonding) has been described as one method of bonding the first mask 205, the anti-reflective coating 213, and the fill material 215, and the third bonding layer 301, this as well is only intended to be illustrative and is not intended to be limiting upon the embodiments. Rather, any suitable method of bonding, such as dielectric-to-dielectric and metal-to-metal bonding, or the like, may also be utilized. Any suitable method of bonding the first mask 205 and the concave surface substrate 201 may be utilized, and all such methods are fully intended to be included within the scope of the embodiments.

By inserting the first mask 205 and then utilizing the first mask 205 as both a hard mask as well as a bonding film, there is a direct cost savings by combining the functionality of multiple layers into a single film. This is in addition to the improved dishing performance that is already obtained through the use of the first mask 205 as a hard mask. As such, there is a lowered cost in addition to the avoidance of defects, voids, and dishing, thereby improving the overall bonding yield.

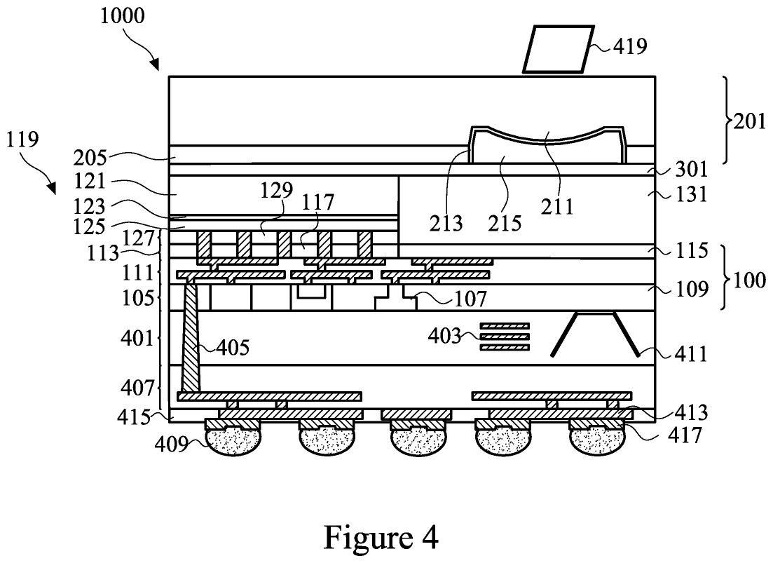

FIG. 4 illustrates a removal of the first substrate 101 and, optionally, the first insulating layer 103, thereby exposing the first active layer 105 of first optical components 107. In an embodiment the first substrate 101 and the first insulating layer 103 may be removed using a planarization process, such as a chemical mechanical polishing process, a grinding process, one or more etching processes, combinations of these, or the like. However, any suitable method may be used in order to remove the first substrate 101 and the first insulating layer 103.

Once the first substrate 101 and the first insulating layer 103 have been removed, a second active layer 401 of fourth optical components 403 may be formed on a back side of the first active layer 105. In an embodiment the second active layer 401 of fourth optical components 403 may be formed using similar materials and similar processes as the first optical components 107 in the first active layer 105 or the second optical components of the metallization layers 111. For example, the second active layer 401 of fourth optical components 403 may be formed of alternating layers of a cladding material such as silicon oxide and core material such as silicon nitride formed using deposition and patterning processes in order to form optical components such as waveguides and the like.

Once the second active layer 401 has been formed, or at any suitable point during the formation of the second active layer 401, a backside mirror 411 may be formed in order to receive light from the concave surface 211 and redirect the light towards the fourth optical components 403 (e.g., an edge coupler formed as one of the fourth optical components 403). To form the backside mirror 411, a second opening (not separately labeled) may be formed in one or more of the layers of the second active layer 401 in the desired location for placement of the backside mirror 411. In accordance with some embodiments, the second opening is formed by one or more etching processes, such as a photolithographic masking and etching process, such as a dry etch process, a wet etch process, the like, or a combination thereof. However, any suitable etching process utilizing any suitable etchants may be used.

Additionally, in some embodiments the etching process may shape the second opening in the desired shape of the backside mirror 411. For example, the sidewalls of the second opening may be formed at a suitable angle to receive light from the concave surface 211 and direct the light into the fourth optical components 403, such as between 42.5 degrees and 54 degrees, e.g., 54 degrees, 45 degrees, or 42.5 degrees. However, any suitable angles may be utilized.

Once the second opening has been formed, a first reflective material may be deposited over the sidewalls of the second opening. In an embodiment, the first reflective material may be deposited through a plating process (e.g., using a seed layer) such as electrical or electro-less plating. The first reflective material may comprise copper, a copper alloy, aluminum, an aluminum alloy, gold, a gold alloy, titanium, a titanium alloy, combinations of these, or the like. However, any suitable material or process may be used.

In some embodiments the first reflective material may fill and/or overfill the second opening, while in other embodiments the first reflective material may fill a portion of the second opening, such as by lining the second opening. In embodiments in which the first reflective material fills a portion of the second opening, a remainder of the second opening may be filled and/or overfilled by a cladding material such as silicon oxide.

Once the second opening has been filled, any excess material located outside of the second opening may be removed using a planarization process. In an embodiment the planarization process may be a chemical mechanical polishing process, whereby etchants and abrasives are utilized with a pad in order to remove excess materials. However, any other suitable method, such as grinding or one or more etching processes, may be utilized.

FIG. 4 also illustrates formation of first through device vias (TDVs) 405, formation of a second metallization layer 407, first external connectors 409, and placement of an optical fiber 419 to form a first optical package 1000. In an embodiment the first through device vias 405 extend through the second active layer 401 and the first active layer 105 so as to provide a quick passage of power, data, and ground through the optical interposer 100. In an embodiment the first through device vias 405 may be formed by initially forming through device via openings into the optical interposer 100. The through device via openings may be formed by applying and developing a suitable photoresist (not shown), and removing portions of the second active layer 401 and the optical interposer 100 that are exposed.

Once the through device via openings have been formed within the optical interposer 100, the through device via openings may be lined with a liner. The liner may be, e.g., an oxide formed from tetraethylorthosilicate (TEOS) or silicon nitride, although any suitable dielectric material may be used. The liner may be formed using a plasma enhanced chemical vapor deposition (PECVD) process, although other suitable processes, such as physical vapor deposition or a thermal process, may alternatively be used.

Once the liner has been formed along the sidewalls and bottom of the through device via openings, a barrier layer (also not independently illustrated) may be formed and the remainder of the through device via openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the through device via openings. Once the through device via openings have been filled, excess liner, barrier layer, seed layer, and first conductive material outside of the through device via openings may be removed through a planarization process such as chemical mechanical polishing (CMP), although any suitable removal process may be used.

Optionally, in some embodiments once the first through device vias 405 have been formed, the second metallization layers 407 may be formed in electrical connection with the first through device vias 405. In an embodiment the second metallization layers 407 may be formed as described above with respect to the first metallization layers 111, such as being alternating layers of dielectric and conductive materials using damascene processes, dual damascene process, or the like. In other embodiments, the second metallization layers may be formed using a plating process to form and shape conductive material, and then cover the conductive material with a dielectric material. However, any suitable structures and methods of manufacture may be utilized.

Of course, the first through device vias 405 and the second metallization layers 407 may be at least partially manufactured simultaneously. For example, one or more layers of the second metallization layers 407 may be manufactured prior to the first through device vias 405, and then the first through device vias 405 may be manufactured through the layers of the second metallization layers 407 that have been formed. Once the first through device vias 405 have been formed, a remainder of the layers of the second metallization layers 407 may be manufactured. Any suitable combination or order of manufacturing steps may be utilized.

Contact pads 413 are formed in electrical connection with the second metallization layers 407. The contact pads 413 may comprise aluminum, but other materials, such as copper, may also be used. The contact pads 413 may be formed using a deposition process, such as sputtering, to form a layer of material (not shown) and portions of the layer of material may then be removed through a suitable process (such as photolithographic masking and etching) to form the contact pads 413. However, any other suitable process may be utilized.

A protection layer 415 may be formed over the contact pads 413. The protective coating is deposited over the wafer using, for example, a curable resin or polyimide coating (e.g., polyimide (PI), polybenzoxazole (PBO), epoxy films, or the like) in order to form the protection layer 415. The protection layer 415 may be deposited via a spin-on technique and then cured using, e.g., a low temperature curing technique. However, any suitable coatings, any suitable deposition techniques, and any suitable curing techniques may also be used.

Once deposited, the protection layer 415 may be patterned using, e.g., a photolithographic masking and etching process, and underbump metallizations (UBMs) 417 may be formed. In an embodiment the UBMs 417 may comprise three layers of conductive materials, such as a layer of titanium, a layer of copper, and a layer of nickel. However, one of ordinary skill in the art will recognize that there are many suitable arrangements of materials and layers, such as an arrangement of chrome/chrome-copper alloy/copper/gold, an arrangement of titanium/titanium tungsten/copper, or an arrangement of copper/nickel/gold, that are suitable for the formation of the UBMs 417. Any suitable materials or layers of material that may be used for the UBMs 417 are fully intended to be included within the scope of the embodiments.

The first external connectors 409 may be formed to provide conductive regions for contact between either the first through device vias 405 or the second metallization layers 407 to other external devices. The first external connectors 409 may be conductive bumps (e.g., C4 bumps, ball grid arrays, microbumps, etc.) or conductive pillars utilizing materials such as solder and copper. In an embodiment in which the first external connectors 409 are contact bumps, the first external connectors 409 may comprise a material such as tin, or other suitable materials, such as silver, lead-free tin, or copper. In an embodiment in which the first external connectors 409 are tin solder bumps, the first external connectors 409 may be formed by initially forming a layer of tin through such commonly used methods such as evaporation, electroplating, printing, solder transfer, ball placement, etc. Once a layer of tin has been formed on the structure, a reflow may be performed in order to shape the material into the desired bump shape.

Optionally at this point in the process, an optical fiber 419 may be attached. In an embodiment the optical fiber 419 is utilized as an optical input/output port to the optical interposer 100. In an embodiment the optical fiber 419 is placed so as to optically couple the optical fiber 419 and an optical input such as a grating coupler that is part of the fourth optical components 403 (through the backside mirror 411). By positioning the optical fiber 419 as such, optical signals leaving the optical fiber 419 are directed towards, e.g., the fourth optical components 403. Similarly, the optical fiber 419 is positioned so that optical signals leaving the fourth optical components 403 are directed into the optical fiber 419 for transmission. However, any suitable location may be utilized.

The optical fiber 419 may be held in place using, e.g., an optical glue (not separately illustrated in FIG. 4). In some embodiments, the optical glue comprises a polymer material such as epoxy-acrylate oligomers, and may have a refractive index between about 1 and about 3. However, any suitable material may be utilized.

Additionally, while the optical fiber 419 may be attached at this point in the manufacturing process, this is intended to be illustrative and is not intended to be limiting. Rather, the optical fiber 419 may be attached at any suitable point in the process. Further, any suitable point of attachment may be utilized, and all such attachments at any point in the process are fully intended to be included within the scope of the embodiments.

By inserting the first mask 205 and then utilizing the first mask 205 as both a hard mask as well as a bonding film, there is a direct cost savings by combining the functionality of multiple layers into a single film. This is in addition to the improved dishing performance that is obtained through the use of the first mask 205 as a hard mask. As such, there is a lowered cost in addition to the avoidance of defects, voids, and dishing, thereby improving the overall bonding yield.

In an embodiment, a method of manufacturing an optical device includes: depositing a first mask 205 over a support material 203; forming a concave surface 211 in the support material 203 through the first mask 205; and bonding the first mask 205 to a first bonding layer 301 over an optical interposer 100. In an embodiment the first mask is silicon oxide. In an embodiment the bonding the first mask to the first bonding layer is performed with a fusion bonding process. In an embodiment an electrical integrated circuit device is located between the first bonding layer and the optical interposer. In an embodiment the method further includes: depositing an anti-reflective layer over the concave surface; and depositing a fill material over the concave surface. In an embodiment the method further includes planarizing the fill material and the anti-reflective layer with the first mask. In an embodiment the anti-reflective layer includes: a first layer comprising silicon oxide; and a second layer comprising silicon nitride.

In another embodiment, a method of manufacturing an optical device includes: bonding an electrical integrated circuit 119 to an optical interposer 100; depositing a bonding layer 301 over the electrical integrated circuit 119; and bonding a first mask 205 of a concave surface substrate 201 to the bonding layer 301, the concave surface substrate 201 comprising a support material 203 different from the first mask 205. In an embodiment the first mask comprises silicon oxide. In an embodiment the concave surface substrate further includes: an anti-reflective layer adjacent to a concave surface and in physical contact with the first mask; and a fill material adjacent to the anti-reflective layer. In an embodiment the anti-reflective layer comprises alternating layers of silicon oxide and silicon nitride. In an embodiment the first mask comprises a first material and wherein the fill material comprises the first material and a first dopant. In an embodiment the method includes, after the bonding the first mask, forming an active layer of optical components on an opposite side of the optical interposer from the concave surface substrate. In an embodiment the method includes forming a backside mirror adjacent to the optical components of the active layer.

In yet another embodiment an optical device includes: a concave surface substrate 201, the concave surface substrate 201 including: a support material 203; a first mask material 205 different from the support material 203; and a concave surface 211 formed within the support material 203; a bonding layer 301 bonded to the first mask material 205; an electrical integrated circuit 119 adjacent to the bonding layer 301; and an optical interposer 100 bonded to the electrical integrated circuit 119. In an embodiment the first mask material comprises silicon oxide. In an embodiment the support material comprises silicon. In an embodiment the concave surface substrate further includes: an anti-reflective layer adjacent to the concave surface; and a fill material adjacent to the anti-reflective layer and planar with the first mask material. In an embodiment the optical device further includes an active layer of optical components located on an opposite side of the optical interposer from the concave surface substrate. In an embodiment the optical device further includes a metallization layer located on an opposite side of the active layer from the optical interposer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an optical device, the method comprising:
depositing a first mask over a support material;
forming a concave surface in the support material through the first mask; and
bonding the first mask to a first bonding layer over an optical interposer.

2. The method of claim 1, wherein the first mask is silicon oxide.

3. The method of claim 1, wherein the bonding the first mask to the first bonding layer is performed with a fusion bonding process.

4. The method of claim 1, wherein an electrical integrated circuit device is located between the first bonding layer and the optical interposer.

5. The method of claim 1, further comprising:
depositing an anti-reflective layer over the concave surface; and
depositing a fill material over the concave surface.

6. The method of claim 5, further comprising planarizing the fill material and the anti-reflective layer with the first mask.

7. The method of claim 6, wherein the anti-reflective layer comprises:
a first layer comprising silicon oxide; and
a second layer comprising silicon nitride.

8. A method of manufacturing an optical device, the method comprising:
bonding an electrical integrated circuit to an optical interposer;
depositing a bonding layer over the electrical integrated circuit; and
bonding a first mask of a concave surface substrate to the bonding layer, the concave surface substrate comprising a support material different from the first mask.

9. The method of claim 8, wherein the first mask comprises silicon oxide.

10. The method of claim 8, wherein the concave surface substrate further comprises:
an anti-reflective layer adjacent to a concave surface and in physical contact with the first mask; and
a fill material adjacent to the anti-reflective layer.

11. The method of claim 10, wherein the anti-reflective layer comprises alternating layers of silicon oxide and silicon nitride.

12. The method of claim 10, wherein the first mask comprises a first material and wherein the fill material comprises the first material and a first dopant.

13. The method of claim 8, after the bonding the first mask, forming an active layer of optical components on an opposite side of the optical interposer from the concave surface substrate.

14. The method of claim 13, further comprising forming a backside mirror adjacent to the optical components of the active layer.

15. An optical device comprising:
a concave surface substrate, the concave surface substrate comprising:
a support material;
a first mask material different from the support material; and
a concave surface formed within the support material;
a bonding layer bonded to the first mask material;
an electrical integrated circuit adjacent to the bonding layer; and
an optical interposer bonded to the electrical integrated circuit.

16. The optical device of claim 15, wherein the first mask material comprises silicon oxide.

17. The optical device of claim 16, wherein the support material comprises silicon.

18. The optical device of claim 15, wherein the concave surface substrate further comprises:
an anti-reflective layer adjacent to the concave surface; and
a fill material adjacent to the anti-reflective layer and planar with the first mask material.

19. The optical device of claim 15, further comprising an active layer of optical components located on an opposite side of the optical interposer from the concave surface substrate.

20. The optical device of claim 19, further comprising a metallization layer located on an opposite side of the active layer from the optical interposer.
